(19) United States
(12) Patent Application Publication
(10) Pub. No.: US 2021/0150108 A1
(43) Pub. Date: May 20, 2021

(54) Automatic Transmission Method

(71) Applicants: Hyundai Motor Company, Seoul (KR); Kia Motors Corporation, Seoul (KR)

(72) Inventors: Dong Hoon Jeong, Hwaseong-si (KR); Byeong Wook Jeon, Seoul (KR); Jae Chang Kook, Hwaseong-si (KR); Kwang Hee Park, Suwon-si (KR)

(21) Appl. No.: 16/944,845

(22) Filed: Jul. 31, 2020

(30) Foreign Application Priority Data
Nov. 14, 2019 (KR) 10-2019-0146139

(51) Int. Cl. G06F 30/27; G06N 3/08; G06N 3/04; G06N 20/20

(52) U.S. Cl. CPC G06F 30/27; G06N 20/20; G06N 3/0454; G06N 3/08

(57) ABSTRACT

A method can be used for modeling an automatic transmission using an artificial neural network. The method includes generating the artificial neural network (ANN) by combining a plurality of fully connection neural networks (FCNNs) with a multi-layer recurrent neural network (RNN) and training the artificial neural network using input data and output data of the automatic transmission. The input data might include a preset gear stage, a target gear stage, a current signal of a clutch hydraulic actuator, and an engine torque and the output data might include an engine revolution per minute (RPM), a turbine RPM, a transmission output RPM, and a vehicle acceleration. The trained artificial neural network can be determined as a model of the automatic transmission.

### CROSS-REFERENCE TO RELATED APPLICATIONS

This application claims priority to Korean Patent Application No. 10-2019-0146139, filed in the Korean Intellectual Property Office on Nov. 14, 2019, which application is hereby incorporated herein by reference.

### TECHNICAL FIELD

The present disclosure relates to an automatic transmission method.

### BACKGROUND

In general, deep learning (deep neural network) is one type of machine learning and includes an artificial neural network (ANN) having multiple layers between an input and an output. The ANN may include a convolution neural network (CNN) or a recurrent neural network (RNN) depending on an architecture, a problem to be solved, and an object.

Data input into the CNN is classified into a training set and a test set. The CNN learns a weight of the neural network based on the training set and verifies the learning result based on the test set.

In such a CNN, when data is input, operations are gradually performed from an input layer to a hidden layer and the results of the operations are output. In this procedure, the input data passes through all nodes only once. The passing of the data through the all nodes only once refers to that the CNN has an architecture which is not based on a data sequence, that is, in a time aspect. Accordingly, the CNN performs learning regardless of the time sequence of input data.

Meanwhile, the CNN has an architecture in which a result of a hidden layer at a previous node is used as an input of a hidden layer at a next node. This refers to that such an architecture is based on a time sequence of the input data.

Such a CNN, which is a deep learning model for learning data changing in a time flow such as time-series data, is an artificial neural network configured through network connection at a reference time point (t) and at a next time point (t+1).

The CNN, in which the connection between units constituting the artificial neural network forms a directed cycle, representatively includes a fully recurrent network (FRN), an echo state network (SEN), a long short term memory network (LSTM), and a continuous-time RNN (CTRNN).

The CNN may include a plurality of cyclic neural network blocks depending on the number of time-series data. CNNs are may be stacked at multiple layers. In this case, a full connection neural network (FCNN) may be used to connect between the CNNs.

According to a conventional method for modeling an automatic transmission, after generating a motion equation for the automatic transmission, considerable know-how is required and time is significantly taken in the process of modifying the motion equation to match multiple test data to the motion equation.

The matter described in the Background art may be made for the convenience of explanation, and may include matters other than a prior art well known to those skilled in the art.

### SUMMARY

The present disclosure relates to a technology of generating a model representing the relationship between an input signal and an output signal of an automatic transmission using an artificial neural network.

The present disclosure has been made to solve the above-mentioned problems occurring in the prior art while advantages achieved by the prior art are maintained intact.

An aspect of the present disclosure provides a method for modeling an automatic transmission using an artificial neural network capable of inputting a result, which is estimated using an initial value and an output of a recurrent neural network (RNN) block, and the output of the RNN block into an RNN block at a next layer, in the artificial neural network generated by combining a plurality of fully connection neural networks (FCNN) and a multi-layer RNN, thereby estimating a final output value having a higher accuracy even if the number of RNN blocks at each layer and the number of the layers are increased.

The technical problems to be solved by the present inventive concept are not limited to the aforementioned problems, and any other technical problems not mentioned herein will be clearly understood from the following description by those skilled in the art to which the present disclosure pertains.

According to an aspect of the present disclosure, a method for modeling an automatic transmission using an artificial neural network may include generating an artificial neural network (ANN) by combining a plurality of fully connection neural networks (FCNNs) with a multi-layer recurrent neural network, training the artificial neural network using input data and output data of the automatic transmission, and determining the trained artificial neural network as a model of the automatic transmission.

According to an embodiment of the present disclosure, the artificial neural network may have an architecture to input a result, which is estimated using an initial value and an output of a recurrent neural network (RNN) block, and the output of the RNN block into an RNN block at a next layer.

According to an embodiment of the present disclosure, the artificial neural network may have an architecture, in which an RNN including a plurality of RNN blocks has multiple layers, and the RNN blocks at the multiple layers are connected with each other through the FCNN.

According to an embodiment of the present disclosure, the training of the artificial neural network may include inputting an initial value and an output of a first RNN block at each layer into a first FCNN at the layer, and inputting a result estimated by the first FCNN at the layer into a second FCNN at the layer.

According to an embodiment of the present disclosure, the inputting of the result into the second FCNN may include inputting a result estimated by a first FCNN into a second FCNN, at a first layer, inputting a result estimated by a first FCNN into a second FCNN, at a second layer, and inputting a result estimated by a first FCNN into a second FCNN, at a third layer.

According to an embodiment of the present disclosure, the inputting of the result into the second FCNN may further include inputting the result estimated by the first FCNN at the first layer into a first RNN block at the second layer, inputting the result estimated by the first FCNN at the second layer into a first RNN block at the third layer, and inputting the result estimated by the first FCNN at the third layer as an output value for an input value.

According to an embodiment of the present disclosure, the input data may include at least one of a preset gear stage, a target gear stage, a current signal of a clutch hydraulic actuator, and an engine torque.

According to an embodiment of the present disclosure, the output data may include at least one of an engine revolution per minute (RPM), a turbine RPM, a transmission output RPM, or a vehicle acceleration.

According to another aspect of the present disclosure, a method for modeling an automatic transmission using an artificial neural network may include generating an architecture to input a result, which is estimated using an initial value and an output of an RNN block, and the output of the RNN block into an RNN block at a next layer, and modeling the automatic transmission using the generated artificial neural network.

According to an embodiment of the present disclosure, the artificial neural network may have an architecture, in which an RNN including a plurality of RNN blocks has multiple layers, and the RNN blocks at the multiple layers are connected with each other through the FCNN.

According to an embodiment of the present disclosure, the training of the artificial neural network may include inputting an initial value and an output of a first RNN block at each layer into a first FCNN at the layer, and inputting a result estimated by the first FCNN at the layer into a second FCNN at the layer.

According to an embodiment of the present disclosure, the inputting of the result into the second FCNN may further include inputting a result estimated by a first FCNN into a second FCNN, at a first layer, inputting a result estimated by a first FCNN into a second FCNN, at a second layer, and inputting a result estimated by a first FCNN into a second FCNN, at a third layer.

According to an embodiment of the present disclosure, the inputting of the result into the second FCNN may further include inputting the result estimated by the first FCNN at the first layer into a first RNN block at the second layer, inputting the result estimated by the first FCNN at the second layer into a first RNN block at the third layer, and inputting the result estimated by the first FCNN at the third layer as an output value for an input value.

According to an embodiment of the present disclosure, the input data may include at least one of a preset gear stage, a target gear stage, a current signal of a clutch hydraulic actuator, and an engine torque.

According to an embodiment of the present disclosure, the output data may include at least one of an engine RPM, a turbine RPM, a transmission output RPM, or a vehicle acceleration.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating a computing system to execute a method for modeling an automatic transmission using an artificial neural network, according to an embodiment of the present disclosure;

FIG. 2 is a flowchart illustrating a method for modeling an automatic transmission using an artificial neural network, according to an embodiment of the present disclosure;

FIG. 3 is a view illustrating an artificial neural network to model an automatic transmission, according to an embodiment of the present disclosure;

FIG. 4 is a view illustrating a horizontal flow of an initial value in an artificial neural network to model an automatic transmission, according to an embodiment of the present disclosure; and

FIG. 5 is a flowchart illustrating a method for modeling an automatic transmission using an artificial neural network, according to an embodiment of the present disclosure.

### DETAILED DESCRIPTION OF ILLUSTRATIVE EMBODIMENTS

Hereinafter, some embodiments of the present disclosure will be described in detail with reference to the exemplary drawings. In adding the reference numerals to the components of each drawing, it should be noted that the identical or equivalent component is designated by the identical numeral even when they are displayed on other drawings. Further, in describing the embodiment of the present disclosure, a detailed description of well-known features or functions will be ruled out in order not to unnecessarily obscure the gist of the present disclosure

In describing the components of the embodiment according to the present disclosure, terms such as first, second, “A”, “B”, (a), (b), and the like may be used. These terms merely intend to distinguish one component from another component, and the terms do not limit the nature, sequence or order of the constituent components. In addition, unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

In the present invention, an automatic transmission means all transmissions except a manual transmission. For example, the automatic transmission may include DCT (Dual Clutch Transmission), CVT (Continuously Variable Transmission), fusion transmission, hybrid transmission, and the like.

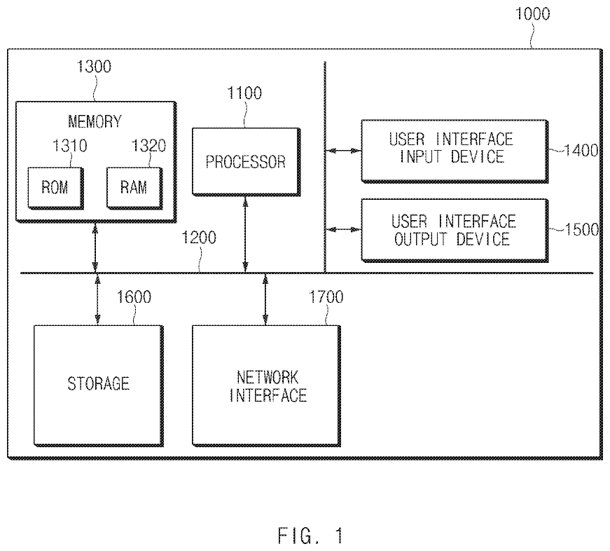

FIG. 1 is a block diagram illustrating a computing system to execute a method for modeling an automatic transmission using an artificial neural network, according to an embodiment of the present disclosure.

Referring to FIG. 1, according to an embodiment of the present disclosure, the method for modeling the automatic transmission using the artificial neural network may be implemented through a computing system. A computing system 1000 may include at least one processor 1100, a memory 1300, a user interface input device 1400, a user interface output device 1500, a storage 1600, and a network interface 1700, which are connected with each other via a system bus 1200

The processor 1100 may be a central processing unit (CPU) or a semiconductor device for processing instructions stored in the memory 1300 and/or the storage 1600. Each of the memory 1300 and the storage 1600 may include various types of volatile or non-volatile storage media. For example, the memory 1300 may include a read only ROM 1310 and a RAM 1320.

Thus, the operations of the methods or algorithms described in connection with the embodiments disclosed in the present disclosure may be directly implemented with a hardware module, a software module, or the combinations thereof, executed by the processor 1100. The software module may reside on a storage medium (i.e., the memory 1300 and/or the storage 1600), such as a RAM memory, a flash memory, a ROM, memory an erasable and programmable ROM (EPROM), an electrically EPROM (EEPROM), a register, a hard disc, a solid state drive (SSD), a removable disc, or a compact disc-ROM (CD-ROM). The exemplary storage medium may be coupled to the processor 1100. The processor 1100 may read out information from the storage medium and may write information in the storage medium. Alternatively, the storage medium may be integrated with the processor 1100. The processor and storage medium may reside in an application specific integrated circuit (ASIC). The ASIC may reside in a user terminal. Alternatively, the processor and storage medium may reside as separate components of the user terminal.

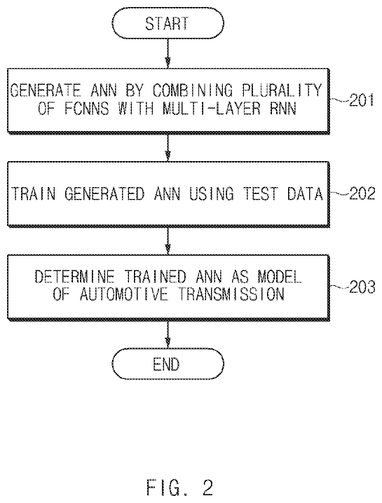

FIG. 2 is a flowchart illustrating a method for modeling an automatic transmission using an artificial neural network, according to an embodiment of the present disclosure, and illustrates a procedure performed by the processor 1100.

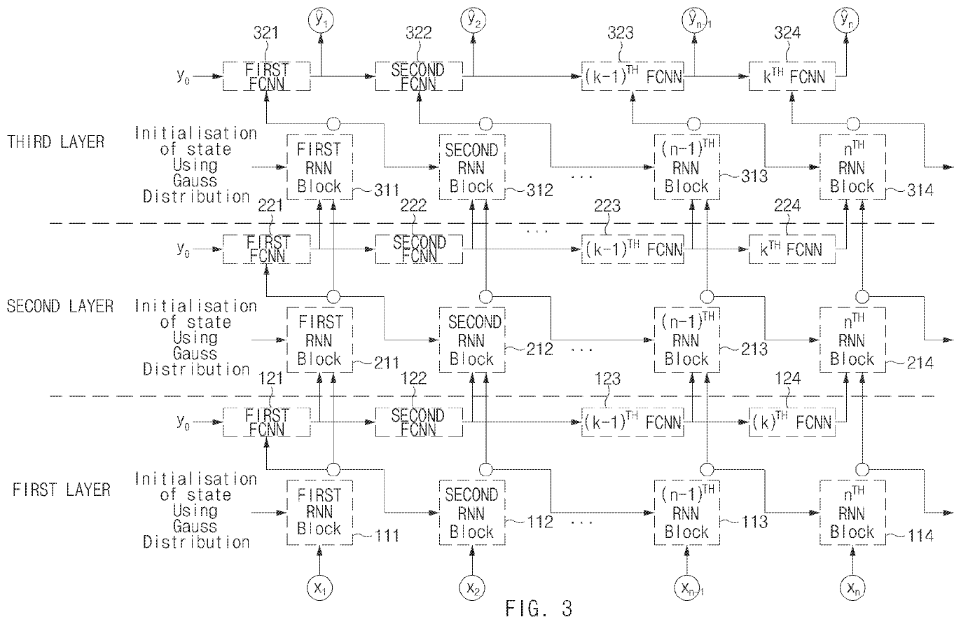

First, the processor 1100 generates an artificial neural network (ANN) by combining a plurality of FCNNs and a multi-layer RNN (201). In this case, the ANN may have an architecture to input a result, which is estimated using an initial value and an output of a RNN block, and the output of the RNN block into an RNN block at a next layer. For example, the processor 1100 may generate an ANN as illustrated in FIG. 3.

Thereafter, the processor 1100 trains the generated ANN using test data (202). For example, the processor 1100 may train the ANN to input, as the input value, a preset gear stage, a target gear stage, a current signal of a clutch hydraulic actuator, and an engine torque, and output, as an output value, an engine revolution per minute (RPM), a turbine RPM, a transmission output RPM, and a vehicle acceleration.

Thereafter, the processor 1100 determines the trained ANN as a model of the automatic transmission (203).

The automatic transmission is modeled in such a manner, so modeling is possible more efficiently with a higher accuracy within a shorter time of period as compared to a conventional method for modeling an automatic transmission based on a motion equation.

Meanwhile, the model of the automatic transmission may be expressed as a function (f) of a relationship of M transmission output signals to N transmission input signals (control signals) for a reference time (T=n), and expressed as following Equation 1. In this case, the automatic transmission may be regarded as a function (f) to map xᵢ to yᵢ.

(y₁,y₂, . . . ,yₙ)=f(x₁,x₂, . . . ,xₙ), xᵢ∈x:R^{N},yᵢ∈x:R^{M} Equation 1

On the assumption that time-series data of the input signal (xᵢ) are X=(x₁, x₂, . . . , yₙ), and the time-series data of the output signal (yᵢ) are Y=(y₁, y₂, . . . , yₙ), k test data (X, Y) may be expressed in the form of a set (D) as illustrated in following Equation 2.

D={(X,Y)|(X₁,Y₁), . . . (X_{K},Y_{K}) Equation 2

Accordingly, the modeling for the automatic transmission may be defined to find a function (h) approximating to a function (f). This may be a procedure of generating an ANN, and training the generated ANN using test data related to the input/output of the automatic transmission, as illustrated in FIG. 3.

FIG. 3 is a view illustrating an artificial neural network to model an automatic transmission, according to an embodiment of the present disclosure.

As illustrated in FIG. 3, according to an embodiment of the present disclosure, the ANN may include three layers and n ‘RNN’ blocks at each layer. The number of layers and the number of RNN blocks at each layer may be varied depending on the intension of a designer.

At the first layer, a first RNN block 111 receives a first input value (x₁) and inputs an output value of the first RNN block 111 into a first FCNN 121 and a first RNN block 211 at a second layer. In this case, the output value of the first RNN block 111 is input into a second RNN block 112. In addition, the first FCNN 121 receives an initial value (y₁) and the output value of the first RNN block 111 and inputs an output value of the first FCNN 121 into the first RNN block 211 at a second layer and a second FCNN 122 at the first layer.

At the first layer, the second RNN block 112 receives a second input value (x₂) and the output value of the first RNN block 111 and inputs an output value of the second RNN block 112 into a second RNN block 212 at the second layer. In this case, the output value of the second RNN block 112 is input into a (n−1)^{th} RNN block 113. In addition, the second FCNN 122 receives the output value of the first FCNN 121 and inputs an output value of the second FCNN 122 into the second RNN block 212 at the second layer and a (k−1)^{th} FCNN 123 at the first layer.

This procedure may be performed until the final output value (ŷₙ) for the final input value (xₙ) is estimated.

At the second layer, the first RNN block 211 receives the output value of the first FCNN 121 at the first layer and the output value of the first RNN block 111 at the first layer and inputs the output value of the first RNN block 211 into a first RNN block 311 at a third layer. In this case, the first RNN block 211 inputs the output value of the first RNN block 211 into the second RNN block 212. In addition, a first FCNN 221 receives the initial value (y₀) and an output value of the first RNN block 211 and inputs an output value of the first FCNN 221 into the first RNN block 311 at the third layer and a second FCNN 222 at the second layer.

At the second layer, the second RNN block 212 receives the output value of the second FCNN 122 at the first layer and the output value of the second RNN block 112 at the first layer and inputs the output value of the second RNN block 212 into a second RNN block 312 at the third layer. In this case, the second RNN block 212 inputs the output value of the second RNN block 212 into an (n−1)^{th} RNN block 213. In addition, the second FCNN 222 receives the output value of the first FCNN 221 and inputs an output value of the second FCNN 222 into the second RNN block 312 at the third layer and a (k−1)^{th} FCNN 223 at the second layer.

This procedure may be performed until the final output value (ŷₙ)) for the final input value (xn) is estimated.

At the third layer, the first RNN block 311 receives the output value of the first FCNN 221 at the second layer and the output value of the first RNN block 211 at the second layer and inputs the output value of the first RNN block 311 into a first FCNN 321. In this case, the first RNN block 311 inputs the output value of the first RNN block 311 into the second RNN block 312. In addition, the first FCNN 321 receives the initial value (y₀) and the output value of the first RNN block 311, inputs an output value of the first FCNN 321 into a second FCNN 322, and outputs the output value of the first FCNN 321 as a final output value (ŷ₁) for the first input value (x₁).

At the third layer, the second RNN block 312 receives the output value of the second FCNN 222 at the second layer and the output value of the second RNN block 212 at the second layer and inputs the output value of the second RNN block 312 to the second FCNN 322. In this case, the second RNN block 312 inputs the output value of the second RNN block 312 into an (n−1)^{th} RNN block 313. In addition, the second FCNN 322 receives an output value of the first FCNN 321, and inputs an output value of the second FCNN 322 into a (k−1)^{th} FCNN 323. In this case, the second FCNN 322 outputs the output value of the second FCNN 322 as a final output value (ŷ₂) for the second input value (x₂).

This procedure may be performed until the final output value (ŷₙ)) for the final input value (xₙ) is estimated.

According to an embodiment of the present disclosure, the best performance is expressed when the ANN includes three layers and 36 RNN blocks at each layer.

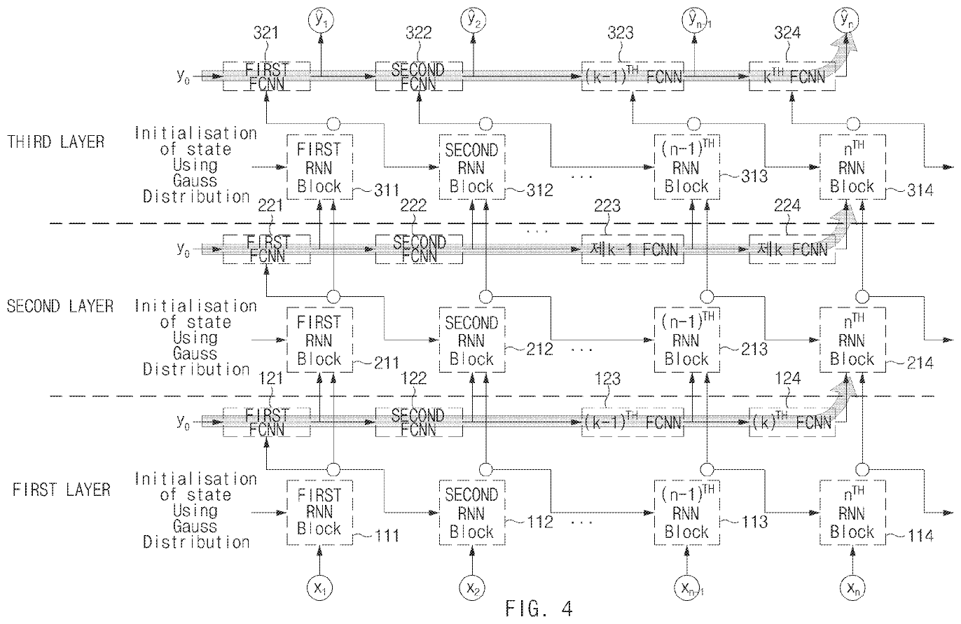

FIG. 4 is a view illustrating a horizontal flow of an initial value in an artificial neural network to model an automatic transmission, according to an embodiment of the present disclosure.

At the first layer, the initial value (y₀) is input into the first FCNN 121, and output of the first FCNN 121 is input into the second FCNN 122. The output of the second FCNN 122 is input into the (k−1)^{th} FCNN 123, and the output of the (k−1)^{th} FCNN 123 is input into the kth FCNN 124.

At the second layer, the initial value (y₀) is input into the first FCNN 221, and the output of the first FCNN 221 is input into the second FCNN 222. The output from the second FCNN 222 is input into the (k−1)^{th} FCNN 223, and the output of the (k−1)^{th} FCNN 223 is input into the kth FCNN 224.

At the third layer, the initial value (y₀) is input into the first FCNN 321, and the output of the first FCNN 321 is input into the second FCNN 322. The output from the second FCNN 322 is input into the (k−1)^{th} FCNN 323, and the output of the (k−1)^{th} FCNN 323 is input into the kth FCNN 324.

As described above, the initial value is influenced in a horizontal direction at each layer. Accordingly, even if the number of RNN blocks at each layer and the number of the layers are increased, the final output values may be estimated with higher accuracy.

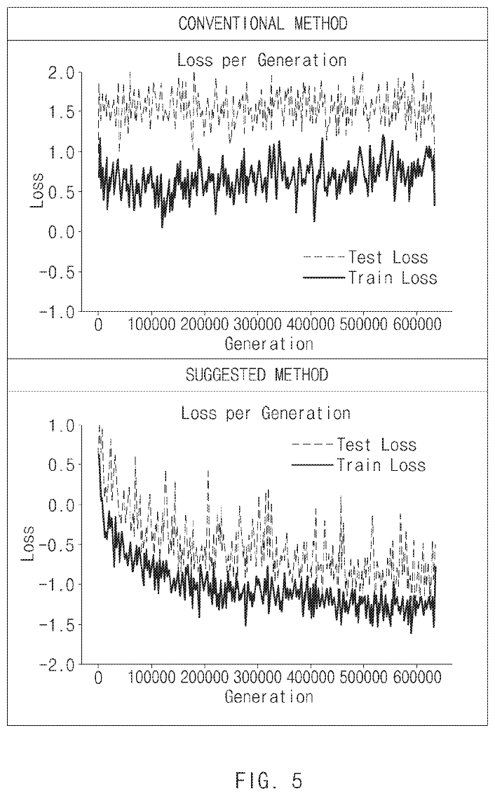

FIG. 5 is a flowchart illustrating a method for modeling an automatic transmission using an artificial neural network, according to an embodiment of the present disclosure.

As illustrated in FIG. 5, according to a conventional method for modeling an automatic transmission, data loss is increased in each epoch. Accordingly, the estimation performance may be degraded.

Meanwhile, according to the suggested invention, less data loss in each epoch is represented, so the higher estimation performance may be represented.

According to an embodiment of the present disclosure, in the method for modeling the automatic transmission using the artificial neural network, the result, which is estimated using the initial value and the output of a recurrent neural network (RNN) block, and the output of the RNN block may be input into an RNN block at a next layer, in the artificial neural network generated by combining the plurality of FCNNs and the multi-layer RNN, thereby estimating the final output value having the higher accuracy even if the number of RNN blocks at each layer and the number of the layers are increased.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

Therefore, the exemplary embodiments of the present disclosure are provided to explain the spirit and scope of the present disclosure, but not to limit them, so that the spirit and scope of the present disclosure is not limited by the embodiments. The scope of the present disclosure should be construed on the basis of the accompanying claims, and all the technical ideas within the scope equivalent to the claims should be included in the scope of the present disclosure.

What is claimed is:

1. A method for modeling an automatic transmission using an artificial neural network, the method comprising:
generating the artificial neural network (ANN) by combining a plurality of fully connection neural networks (FCNNs) with a multi-layer recurrent neural network (RNN);
training the artificial neural network using input data and output data of the automatic transmission; and
determining the trained artificial neural network as a model of the automatic transmission.

2. The method of claim 1, wherein the artificial neural network has an architecture to input a result that is estimated using an initial value and an output of an RNN block, the output of the RNN block being input into an RNN block at a next layer.

3. The method of claim 1, wherein the artificial neural network has an architecture, in which an RNN including a plurality of RNN blocks has multiple layers, and the RNN blocks at the multiple layers are connected with each other through the FCNNs.

4. The method of claim 3, wherein training the artificial neural network comprises:
inputting an initial value and an output of a first RNN block at each layer into a first FCNN at the layer; and
inputting a result estimated by the first FCNN at the layer into a second FCNN at the layer.

5. The method of claim 4, wherein inputting the result into the second FCNN comprises:
inputting a result estimated by the first FCNN into the second FCNN, at a first layer;
inputting a result estimated by the first FCNN into the second FCNN, at a second layer; and
inputting a result estimated by the first FCNN into the second FCNN, at a third layer.

6. The method of claim 5, wherein inputting the result into the second FCNN further comprises:
inputting the result estimated by the first FCNN at the first layer into the first RNN block at the second layer;
inputting the result estimated by the first FCNN at the second layer into the first RNN block at the third layer; and
inputting the result estimated by the first FCNN at the third layer as an output value for an input value.

7. The method of claim 1, wherein the input data includes at least one of a preset gear stage, a target gear stage, a current signal of a clutch hydraulic actuator, or an engine torque.

8. The method of claim 1, wherein the output data includes at least one of an engine revolution per minute (RPM), a turbine RPM, a transmission output RPM, or a vehicle acceleration.

9. A method for modeling an automatic transmission using an artificial neural network, the method comprising:
generating an architecture to input a result that is estimated using an initial value and an output of an RNN block, and the output of the RNN block into an RNN block at a next layer; and
modeling the automatic transmission using the generated artificial neural network.

10. The method of claim 9, wherein generating the architecture comprises generating the artificial neural network (ANN) by combining a plurality of fully connection neural networks (FCNNs) with a multi-layer recurrent neural network (RNN); and
wherein the architecture comprises an architecture in which an RNN including a plurality of RNN blocks has multiple layers, and the RNN blocks at the multiple layers are connected with each other through the FCNNs.

11. The method of claim 10, wherein modeling the automatic transmission comprises training the artificial neural network by inputting the initial value and an output of a first RNN block at each layer into a first FCNN at the layer and inputting a result estimated by the first FCNN at the layer into a second FCNN at the layer.

12. The method of claim 11, wherein inputting the result into the second FCNN further comprises:
inputting a result estimated by the first FCNN into the second FCNN, at a first layer;
inputting a result estimated by the first FCNN into the second FCNN, at a second layer; and
inputting a result estimated by the first FCNN into the second FCNN, at a third layer.

13. The method of claim 12, wherein inputting the result into the second FCNN further comprises:
inputting the result estimated by the first FCNN at the first layer into the first RNN block at the second layer;
inputting the result estimated by the first FCNN at the second layer into the first RNN block at the third layer; and
inputting the result estimated by the first FCNN at the third layer as an output value for an input value.

14. The method of claim 9, wherein modeling the automatic transmission comprises training the artificial neural network using input data and output data of the automatic transmission, the input data including at least one of a preset gear stage, a target gear stage, a current signal of a clutch hydraulic actuator, or an engine torque.

15. The method of claim 9, wherein modeling the automatic transmission comprises training the artificial neural network using input data and output data of the automatic transmission, the output data including at least one of an engine revolution per minute (RPM), a turbine RPM, a transmission output RPM, or a vehicle acceleration.

16. A method for modeling an automatic transmission using an artificial neural network, the method comprising:
generating the artificial neural network (ANN) by combining a plurality of fully connection neural networks (FCNNs) with a multi-layer recurrent neural network (RNN);
training the artificial neural network using input data and output data of the automatic transmission, the input data including a preset gear stage, a target gear stage, a current signal of a clutch hydraulic actuator, and an engine torque and the output data including an engine revolution per minute (RPM), a turbine RPM, a transmission output RPM, and a vehicle acceleration; and
determining the trained artificial neural network as a model of the automatic transmission.

17. The method of claim 16, wherein the artificial neural network has an architecture, in which an RNN including a plurality of RNN blocks has multiple layers, and the RNN blocks at the multiple layers are connected with each other through the FCNNs.

18. The method of claim 17, wherein training the artificial neural network comprises:
inputting an initial value and an output of a first RNN block at each layer into a first FCNN at the layer; and
inputting a result estimated by the first FCNN at the layer into a second FCNN at the layer.

19. The method of claim 18, wherein inputting the result into the second FCNN comprises:
inputting a result estimated by the first FCNN into the second FCNN, at a first layer;
inputting a result estimated by the first FCNN into the second FCNN, at a second layer; and
inputting a result estimated by the first FCNN into the second FCNN, at a third layer.

20. The method of claim 19, wherein inputting the result into the second FCNN further comprises:
inputting the result estimated by the first FCNN at the first layer into the first RNN block at the second layer;
inputting the result estimated by the first FCNN at the second layer into the first RNN block at the third layer; and
inputting the result estimated by the first FCNN at the third layer as an output value for an input value.
